(19) United States
(12) Patent Application Publication
(10) Pub. No.: US 2010/0089491 A1
(43) Pub. Date: Apr. 15, 2010

(54) Gas Filling Socket, Gas Filling Socket Set, and Gas Filling Apparatus

(76) Inventor: Yung-Shuen PAN, Shulin City (TW)

Correspondence Address: SINORICA, LLC, 2275 Research Blvd., Suite 500, ROCKVILLE, MD, 20850, US

(21) Appl. No.: 12/339,143

(22) Filed: Dec. 19, 2008

(30) Foreign Application Priority Data
Oct. 14, 2008 (TW) 097139294

(51) Int. Cl. F17C 5/00; H01L 21/67

(52) U.S. Cl. 141/21; 206/719; 206/722; 141/59

(57) ABSTRACT

The present invention is related to a gas filling socket, gas filling socket set, and gas filling apparatus. The gas filling socket comprises a carrying base having an upper surface and a lower surface, the upper surface being used to carry a semiconductor storage device or a reticle pod; at least a pair of through holes being set on and through the carrying base; at least one gas input port connecting to one through hole, and at least one gas output port connecting to another through hole, wherein the characteristic of the gas filling socket is that: the upper surface of the carrying base includes an angle guiding board disposed on one side of the carrying base for providing a guiding function to ensure the positioning of the semiconductor storage device or the reticle pod while the semiconductor storage device or the reticle pod is placed into the gas filling socket.

### BACKGROUND OF THE INVENTION

1. Field of the Invention

The present invention is related to a gas filling socket, gas filling socket set, and gas filling apparatus, and more particularly, to a gas filling socket with an angle guiding board for providing a guiding function to ensure the positioning of the semiconductor storage device or the reticle pod while the semiconductor storage device or the reticle pod is placed in the gas filling socket.

2. Description of the Prior Art

In the semiconductor process, the solution to the problem of particle contamination has been continuously and keenly sought by all concerned parties. And to meet the requirements of currently applied Standard Mechanical Interface (SMIF), open storage device is no longer used for storing or transferring components but platform and apparatus adopting SMIF equipment and technology are used in the process of producing, transferring, and storing components for reducing cost of establishing large plants with high level of cleanliness.

To meet the requirements of SMIF technology, the wafer container or reticle pod used for storing or transferring components such as wafer or reticle is filled with nitrogen or inert gas and the level of cleanliness of which is maintained under Class 1, the technology of which being mainstream production technology of current IC production. Taiwan Patent No. M310201, as shown in FIG. 1, discloses a gas filling cleaner for filling gas in storage device of semiconductor component. The gas filling cleaner 1 comprises a case 11, a gas valve unit, a spray nozzle 121, a control unit, and a carrying base 12. The input end of gas valve unit is connected to a gas source, and the output end of gas valve unit is connected to the input end of the spray nozzle 121; the signal of control unit is connected to the gas valve unit for controlling the opening and closing of gas valve unit; the carrying base 12 is connected with the case 11 for carrying a container, and the output end of spray nozzle 121 is disposed on the outer surface of the carrying base 12 for the spray nozzle 121 and the ventilation hole of the container to be connected to each other for the container to be filled with gas. Moreover, in the aforementioned gas filling cleaner 1 a position unit 122 and a detection unit 123 can be further disposed on the carrying base 12, the position unit 122 used for guiding the ventilation hole of the container to be connected to the spray nozzle 121 and the detection unit 123 used for detecting whether the carrying base 12 is already carrying a container for the container to be more accurately placed on the carrying base 12.

However, although a position unit 122 is disposed on the carrying base 12 of gas filling cleaner of the prior art, yet according to the disposition of spray nozzle 121 and position unit 122 in FIG. 1, when the container is loaded onto the carrying base 12, if there is a larger aberration in the position in which the container is loaded, then it is hard for the guiding function of the position unit 122 to be effected. Moreover, when the gas filling cleaner of the prior art fills gas into the container, static electricity is generated due to friction when the gas continues to enter the container and electric charges are accumulated in the gas in the container, making it easier for static electricity on the surface of reticle to attract contaminant particles in the air and even for electrostatic discharge (ESD) effect to occur on metal wire on the reticle. The instant current generated by electrostatic discharge (ESD) will result in spark or arc; when the spark and arc are simultaneously generated, the strong current accompanied by high temperature will cause metal wire to oxidize and dissolute and thus cause change of pattern of reticle or damage to reticle.

### SUMMARY OF THE INVENTION

To solve the aforementioned problems, one objective of the present invention is to provide a gas filling socket for carrying a semiconductor storage device or a reticle pod within a gas filling socket apparatus to maintain the cleanliness of semiconductor component or reticle.

Another objective of the present invention is the provide a gas filling socket, which includes an angle guiding board for providing a guiding function to ensure the positioning of the storage device while the storage device is placed into the gas filling socket.

Still another objective of the present invention is to provide a gas filling socket, which comprises a pair of position blocks disposed at the corner of the carrying base to provide the function of assisting in guiding the positioning of storage device.

Yet another objective of the present invention is to provide a gas filling socket, which comprises a pair of micro switches disposed on the carrying base for checking whether the storage device is securely positioned.

And still another objective of the present invention is to provide a gas filling socket, the area where the gas input/output port of which and the lower surface of carrying base of which contact includes a valve head made of PEEK material for reducing static electricity generated due to friction when gas continues to enter the container.

And yet another objective of the present invention is to provide a gas filling socket, the valve head made of PEEK material of which prevents from accumulation of electric charges in the gas in the container that makes it easier for static electricity on the surface of reticle to attract contaminant particles in the air.

And still another objective of the present invention is to provide a gas filling socket, the valve head made of PEEK material of which prevents from accumulation of electric charges in the gas in the container that causes electrostatic discharge (ESD) effect to occur on metal wire on the reticle and to lead to oxidization and dissolution of metal wire that causes change of pattern of reticle or damage to reticle.

And yet another objective of the present invention is to provide a gas filling socket, the area where the gas input/output port of which and the upper surface of carrying base of which contact includes a pad made of conductive rubber material for conducting the static electricity generated due to friction when the gas continues to enter the container to the exterior of the storage device.

And still another objective of the present invention is to provide a gas filling socket, which comprises a signal detection device for detecting whether the storage device is placed on the carrying base.

According to the objectives described above, the present invention provides a gas filling socket, gas filling socket set, and gas filling apparatus. The gas filling socket comprises a carrying base having an upper surface and a lower surface, the upper surface being used to carry a semiconductor storage device or a reticle pod; at least a pair of through holes being set on and through the carrying base; at least one gas input port connecting to one through hole, and at least one gas output port connecting to another through hole, wherein the characteristic of the gas filling socket is that: the upper surface of the carrying base includes an angle guiding board disposed on one side of the carrying base for providing a guiding function to ensure the positioning of the semiconductor storage device or the reticle pod while the semiconductor storage device or the reticle pod is placed into the gas filling socket.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is an isometric view of a gas filling cleaner (of prior art);

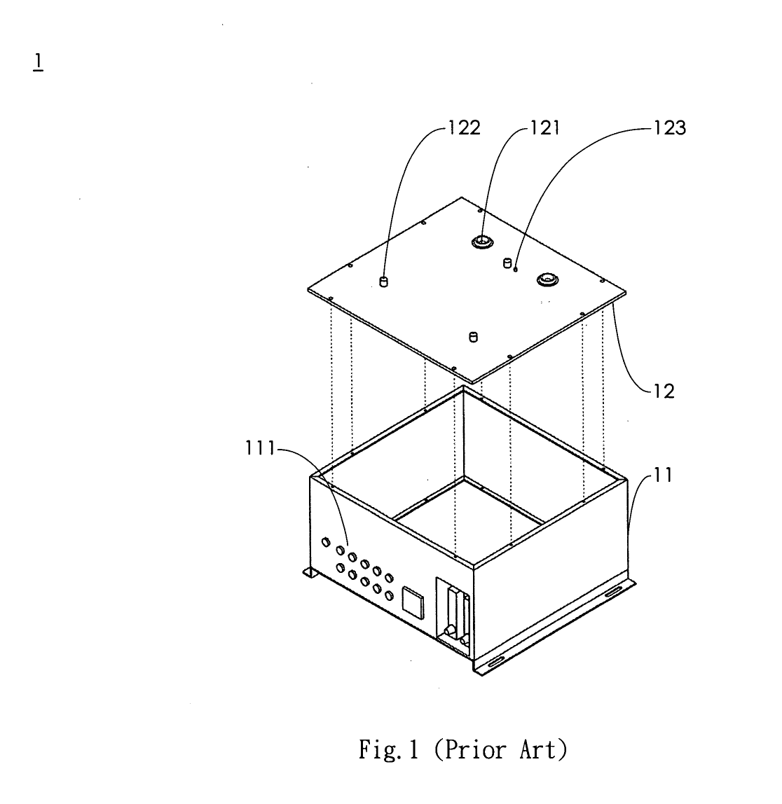

FIG. 2A is an isometric view of upper surface of a gas filling socket;

FIG. 2B is a front view of lower surface of a gas filling socket;

FIG. 3 is an isometric view of a gas filling socket set;

FIG. 4 is a front view of a gas filling apparatus;

FIG. 5 is a view of an EPC cabinet; and

FIG. 6 is a view of an EPC gas loop set.

### DESCRIPTION OF THE PREFERRED EMBODIMENTS

The present invention discloses a gas filling socket, gas filling socket set, and gas filling apparatus, and more particularly, a gas filling socket with an angle guiding board for providing a guiding function to ensure the positioning of a semiconductor storage device a reticle pod while the storage device or the pod is placed into the gas filling socket. In the present invention, some details of gas filling process and operating process of related gas filling apparatus are achieved by applying conventional art, and therefore are not completed depicted in below description. And the drawings referred to in the following are not made according to the actual related sizes, the function of which is only to express and illustrate characteristics of the present invention.

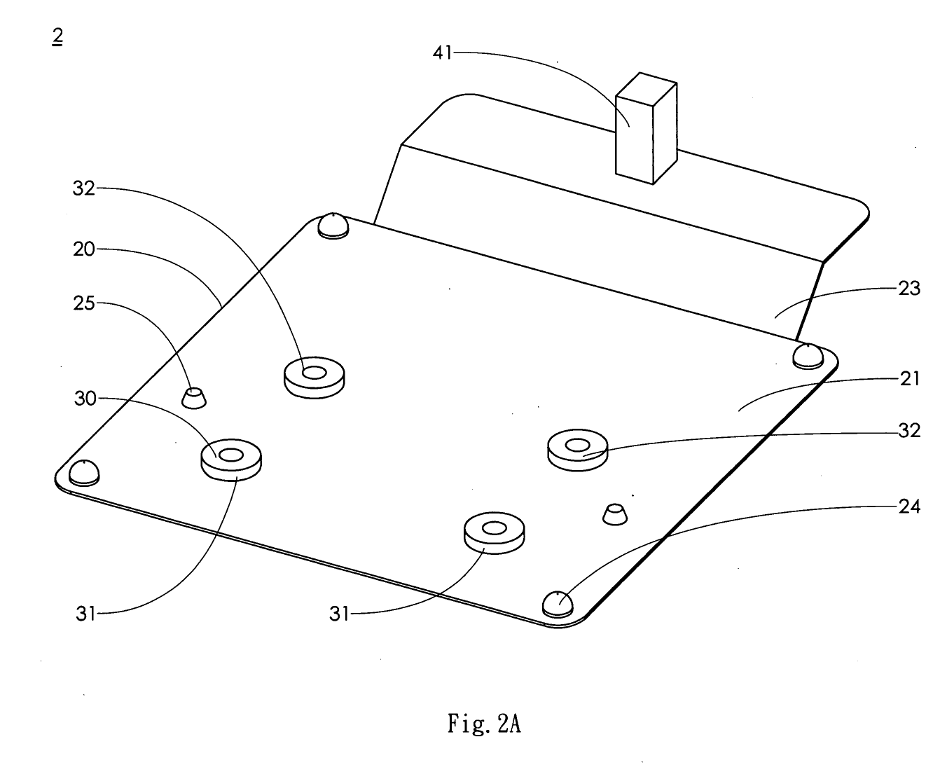

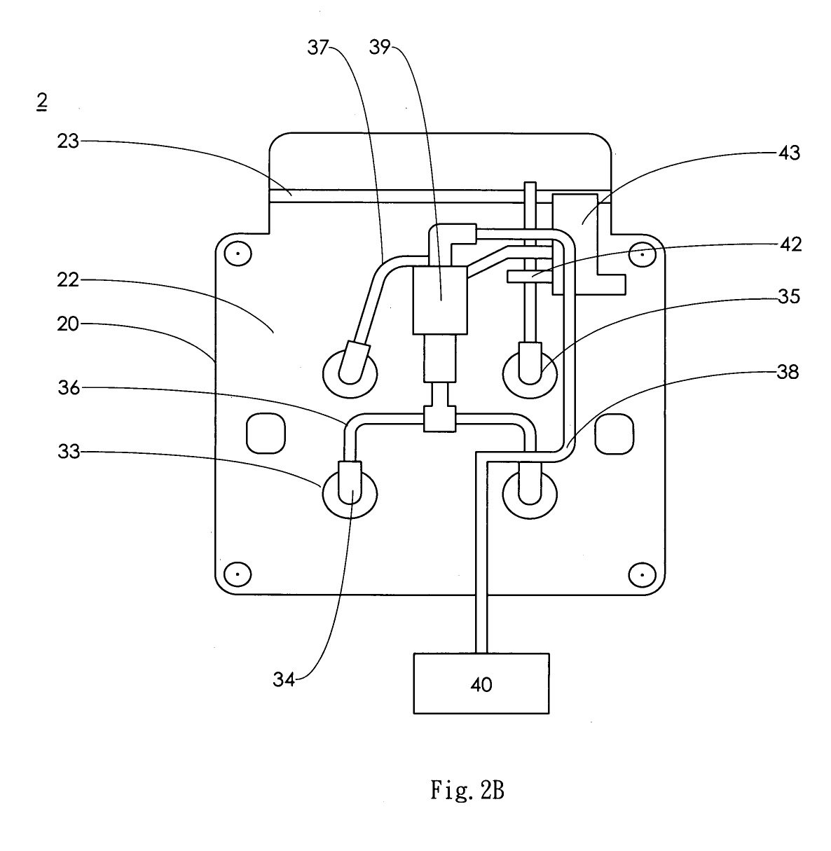

First, referring to FIG. 2A and FIG. 2B, which are views of a preferred embodiment of gas filling socket according to the present invention. As shown in FIG. 2A, gas filling socket 2 comprises a carrying base 20, including an upper surface 21 and a lower surface 22 (referring to FIG. 2B), the upper surface 21 being used for carrying a semiconductor storage device or a reticle pod (not shown in Figure); at least a pair of through holes 30, being set on and through the carrying base 20; at least a gas input port 31 connecting to one of said pair of through holes 30, and at least one gas output port 32 connecting to the other of through hole 30, wherein the characteristic of the gas filling socket 2 is that: the upper surface 21 of the carrying base 20 includes an angle guiding board 23 disposed on one side of the carrying base 20, the degree of inclination of the angle guiding board 23 being 10˜80 degrees, with the angle guiding board 23 a guiding function thus being provided to ensure the positioning of a semiconductor storage device or a reticle pod while the storage device or the pod is placed into the gas filling socket 2.

According to the gas filling socket 2 described above, at least a pair of position blocks 24 or at least a pair of micro switches 25 can be further disposed on the upper surface 21 of the gas filling socket 2, as shown in FIG. 2. At least a pair of position blocks 24 are disposed at the corner of carrying base 20, and a preferred location for disposition is the four corners of carrying base 20, the position blocks 24 being used for restricting the position of semiconductor storage device or reticle pod and assisting in guiding the positioning of the storage device or pod. At least a pair of micro switches 25 can be further disposed on the carrying base 20, and a preferred location for disposition is between the pair of position blocks 24 for checking whether the semiconductor storage device or the reticle pod is accurately placed on the carrying base 20; if the storage device or the pod is checked as being accurately placed, the gas filling apparatus (not shown in Figure) is activated to fill gas, and if the storage device or the pod is checked as not yet being accurately placed or being erroneously placed, an alarm can be sent out.

According to the gas filling socket 2 described above, at least a pair of valve heads 33 can be further disposed on the lower surface 22 of gas filling socket 2, as shown in FIG. 2B. The pair of valve heads 33 are disposed at the lower surface 22 of the carrying base 20 where contacts with the gas input port 31 and the gas output port 32, wherein the pair of valve heads 33 are made of PEEK material for reducing static electricity generated due to friction when gas continues to enter the container and preventing from accumulation of electric charges in the gas in the container that makes it easier for static electricity on the surface of reticle to attract contaminant particles in the air or causes electrostatic discharge (ESD) effect to occur on metal wire on the reticle and to lead to oxidization and dissolution of metal wire that causes change of pattern of reticle or damage to reticle. Moreover, at least a pair of pads (not shown in Figure) can be further disposed on the upper surface 21 of gas filling socket 2, at the contact area between the gas input port 31 and gas output port 32 and the upper surface 21 of the carrying base 20, wherein the pair of pads are made of conductive rubber material for conducting the static electricity generated due to friction when the gas continues to enter the container to the exterior of the storage device.

Furthermore, referring to FIG. 2A, at least a signal detection device 41 is further disposed on the gas filling socket 2, and a preferred location for disposition is on one side of the upper surface 21 of carrying base 20, or on one side of the angle guiding board 23, for detecting whether the semiconductor storage device or the reticle pod is placed on the carrying base 20, the signal detection device 41 being able to be a refractive photoelectric detector or a position detecting device. Then referring to FIG. 2B, an air pressure detection unit 42 is further disposed on the lower surface 22 of carrying base 20, wherein the air pressure detection unit 42 is a micro differential pressure gauge. The air pressure detection unit 42 is connected to the gas output port 32 for detecting the pressure of gas output from the gas output port 32. When the air pressure detection unit 42 detects the air pressure difference between the gas output port 32 and the exterior atmosphere, it generates a micro pressure difference signal and amplifies this micro pressure difference signal. Referring to FIG. 2B, a control unit 43 is further disposed on the lower surface 22 of carrying base 20, wherein this control unit 43 is a XG chip and is used for receiving a signal to control the gas filling-in of the interior of the semiconductor storage device or the reticle pod, the control unit 43 being able to receiving signal command from a programmable control circuit module.

Still referring to FIG. 2B, at least a gas inlet valve 34 is disposed at the input end of gas input port 31 of lower surface 22 of carrying base 20. The gas inlet valve 34 is used for being connected to at least a gas inlet pipe 36, and a gas supply source 40 is provided outside the body of gas filling socket 2. Gas provided by the gas supply source 40 can be XCDA or inert gas, a preferred inert gas being N2, and the gas supply source 40 is at least connected to an exterior gas supply pipe 38. A filter 39 is further disposed on the lower surface 22 of carrying base 20, the input end and output end of which are respectively connected to the exterior gas supply pipe 38 and the gas inlet pipe 36. A gas outlet valve 35 is further disposed at the output end of gas output port 32 of lower surface 22 of carrying base 20 for being connected to at least a gas outlet pipe 37, and the gas outlet pipe 37 is connected to air pressure detection unit 42 for exhausting gas in the storage device or pod out of the device.

According to the structure described above, the way in which the gas filled by the gas filling socket 2 of the present invention flows is as below: a gas is provided by the gas supply source 40 and led into the filter 39 by the exterior air supply pipe 38, and the flow of gas filtered by the filter 39 is then branched via gas inlet pipe 36 and flows into the gas input port 31 through the gas inlet valve 34 connecting to it to be filled in the interior of the storage device and the pod; and after gas is filled, gas can be directly exhausted outside the storage device or pod via the gas outlet valve 35 that is connected to the gas output port 32, or the gas can also be led to the air pressure detection unit 42 through the gas outlet pipe 37 to be exhausted to the exterior of the storage device or the pod for generating and amplifying a micro pressure difference signal.

The semiconductor storage device or reticle pod as described in the present invention is transferred by a machine arm of fully automated storage system and loaded onto the carrying base 20 to complete the loading process.

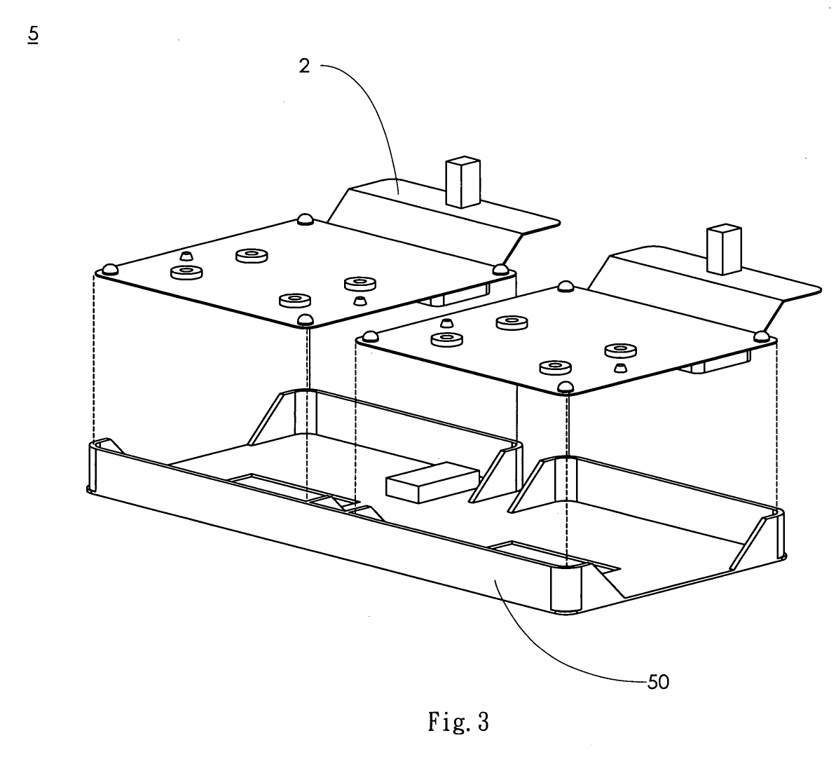

Referring to FIG. 3, which is a view of a preferred embodiment of gas filling socket set according to the present invention. As shown in FIG. 3, the gas filling socket set 5 comprises a socket-connecting base tray 50, which carries at least two gas filling sockets 2. The gas filling socket 2 includes a carrying base 20, and the related structure of carrying base 20 is illustrated by a preferred embodiment of gas filling socket of the present invention.

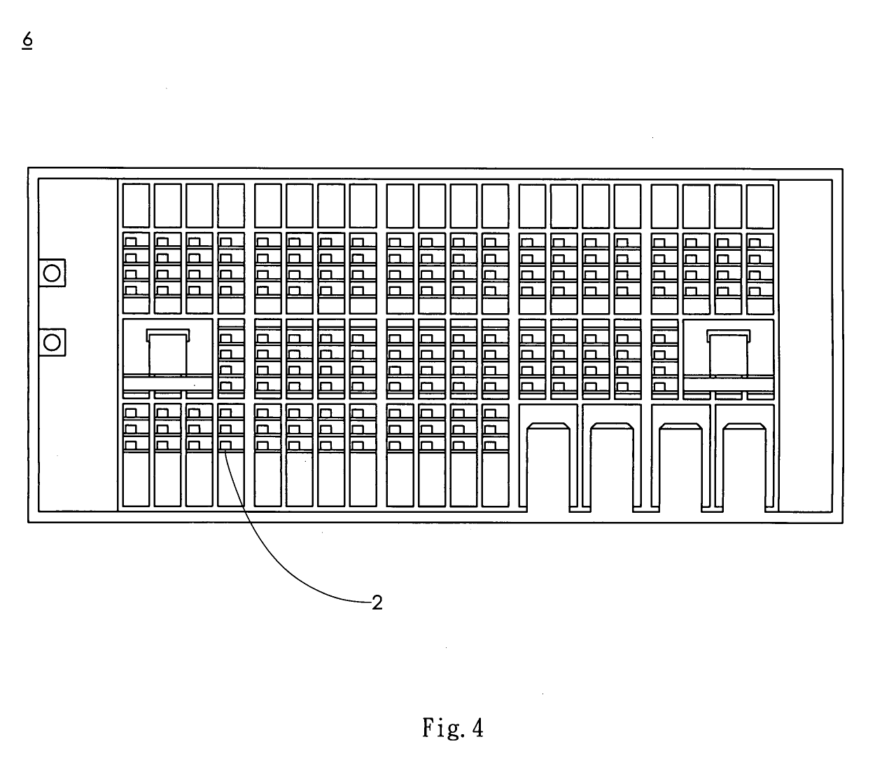

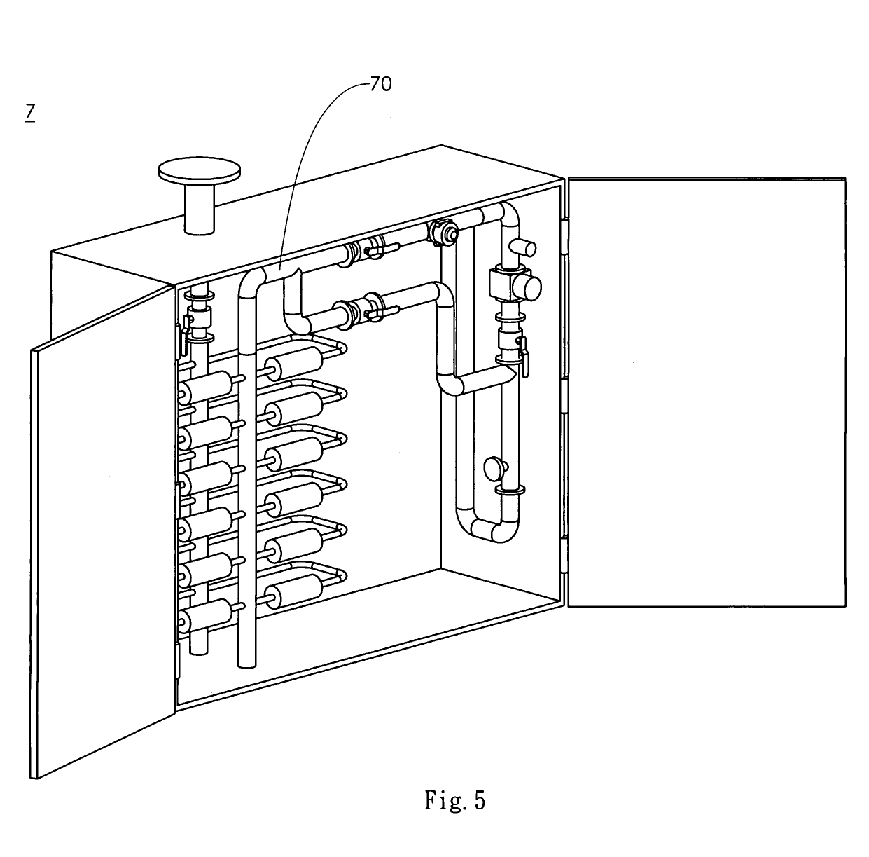

Referring to FIG. 4, which is a view of a preferred embodiment of gas filling apparatus according to the present invention. As shown in FIG. 4, the gas filling apparatus 6 co-operates with the fully automated storage system, leading gas provided by an Electronic Pressure Control (EPC) cabinet 7 (referring to FIG. 5) to at least a semiconductor storage device or a reticle pod. The gas filling apparatus 6 comprises a gas filling socket 2, and the gas filling socket 2 includes a carrying base 20, the related structure of carrying base 20 being illustrated by a preferred embodiment of gas filling socket of the present invention.

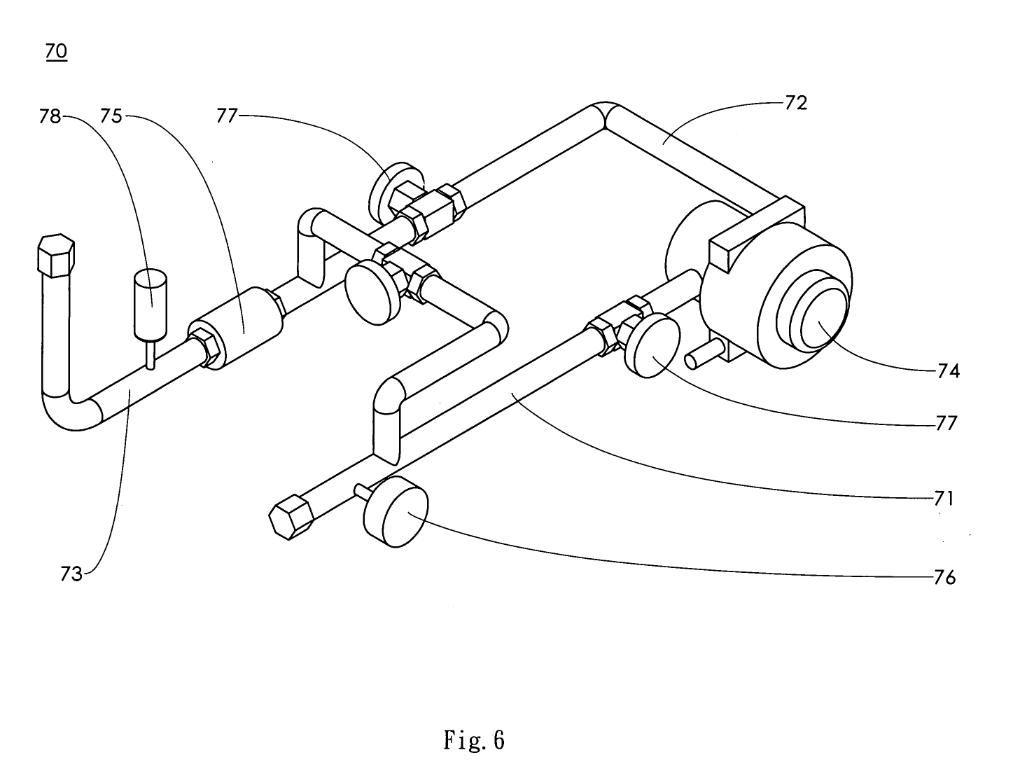

Following what is described above, referring to FIG. 5, the EPC cabinet 7 comprises an EPC gas loop set 70, referring to FIG. 6, which includes a gas inlet pipe 71 for being connected to a gas supply source 40 and receiving gas provided by the gas supply source 40; an EPC device 74 for receiving gas flowing from the gas inlet pipe 71 and appropriately allotting and controlling the outflow of gas; a gas loop 72 for being connected to the EPC device 74 and receiving the outflow of gas; a gas outlet pipe 73 for being connected to the EPC cabinet 7 and outputting gas into the EPC cabinet 7; at least a filter 75, the input end and the output end of which are respectively connected to the gas flow loop 72 and the gas outlet pipe 73.

Moreover, the EPC gas loop set 70 of the present invention further includes a pressure gauge 76 disposed in the gas inlet pipe 71 for measuring the pressure of gas provided by the gas supply source 40, a ball gauge 77 disposed at the input end of the EPC device 74 or the input end of the filter 75 for controlling the turning-on and shutting-off of the gas flow, and a pressure detector 78 disposed at the output end of the filter 75 for detecting the pressure of gas flowing into the EPC cabinet 7.

What are described above are only preferred embodiments of the present invention and are not for limiting the scope of the present invention; and the above description can be understood and put into practice by those who are skilled in the art. Therefore any equivalent modifications and arrangements made without departing from the spirit disclosed by the present invention should be encompassed by the appended claims accorded with the broadest interpretation.

What is claimed is:

1. A gas filling socket, comprising a carrying base with an upper surface and a lower surface, said upper surface being used for carrying a semiconductor storage device or a reticle pod, at least a pair of through holes being set on and through said carrying base, at least a gas input port being connected to one of said pair of through holes and at least a gas output port being connected to the other of said pair of through holes, wherein the characteristic of said gas filling socket is in that:
said upper surface of said carrying base including an angle guiding board disposed on one side of said carrying base.

2. The gas filling socket according to claim 1, wherein degree of inclination of said angle guiding board is 10˜80 degrees.

3. The gas filling socket according to claim 1, further comprising a pair of position blocks disposed at corner of said carrying base.

4. The gas filling socket according to claim 1, further comprising a pair of micro switches disposed on said carrying base.

5. The gas filling socket according to claim 1, further comprising a pair of valve heads are disposed at said lower surface of said carrying base where contacts with said gas input port and said gas output port.

6. The gas filling socket according to claim 1, further comprising a signal detection device for detecting whether said semiconductor storage device or said reticle pod is placed on said carrying base.

7. The gas filling socket according to claim 6, wherein said signal detection device can be selected from the group consisting of: a refractive photoelectric detector and a position detecting device.

8. The gas filling socket according to claim 1, further comprising an air pressure detection unit, disposed on said lower surface of said carrying base and connected to said gas output port for detecting pressure of gas output from said gas output port.

9. The gas filling socket according to claim 1, further comprising a control unit, disposed on said lower surface of said carrying base and used for receiving a signal to control gas filling-in of interior of said semiconductor storage device or said reticle pod.

10. The gas filling socket according to claim 1, wherein said control unit receives signal command from a programmable control circuit module.

11. The gas filling socket according to claim 1, further comprising a gas inlet valve disposed at input end of said gas input port of said lower surface of said carrying base for being connected to at least a gas inlet pipe.

12. The gas filling socket according to claim 1, further comprising a gas outlet valve disposed at output end of said gas output port of said lower surface of said carrying base for being connected to at least a gas outlet pipe.

13. The gas filling socket according to claim 1, wherein said semiconductor storage device or said reticle pod is transferred by a machine arm of a fully automated storage system to be loaded onto said carrying base.

14. A gas filling apparatus, co-operating with fully automated storage system, leading gas provided by an Electronic Pressure Control (EPC) cabinet to at least a semiconductor storage device or a reticle pod, said gas filling apparatus comprising a gas filling socket, said gas filling socket comprising a carrying base with an upper surface and a lower surface, said upper surface being used for carrying a semiconductor storage device or a reticle pod, a pair of through holes being set on and through said carrying base, at least a gas input port being connected to one of said pair of through holes and at least a gas output port being connected to the other of said pair of through holes, wherein the characteristic of said gas filling socket is in that:
said upper surface of said carrying base including an angle guiding board disposed on one side of said carrying base.

15. The gas filling apparatus according to claim 14, wherein said EPC cabinet comprising an EPC gas loop set, comprising:
a gas inlet pipe for being connected to a gas supply source and receiving gas provided by said gas supply source;
an EPC device for receiving gas flowing from said gas inlet pipe and appropriately allotting and controlling outflow of said gas;
a gas loop for being connected to said EPC device and receiving outflow of said gas;
a gas outlet pipe for being connected to said EPC cabinet and outputting gas into said EPC cabinet; and
at least a filter, input end and output end of said filter being respectively connected to said gas flow loop and said gas outlet pipe.

16. The gas filling apparatus according to claim 15, further comprising a pressure gauge disposed in said gas inlet pipe for measuring pressure of gas provided by said gas supply source.

17. The gas filling apparatus according to claim 15, further comprising a ball gauge disposed at input end of said EPC device for controlling turning-on and shutting-off of said gas flow.

18. The gas filling apparatus according to claim 15, further comprising a ball gauge disposed at input end of said filter for controlling turning-on and shutting-off of said gas flow.

19. The gas filling apparatus according to claim 15, further comprising a pressure detector disposed at output end of said filter for detecting pressure of gas flowing into said EPC cabinet.
